(19) United States
(12) Patent Application Publication
(10) Pub. No.: US 2024/0062993 A1
(43) Pub. Date: Feb. 22, 2024

(54) TEMPERATURE-CONTROLLED SHOWERHEAD ASSEMBLY FOR CYCLIC VAPOR DEPOSITION

(71) Applicant: Eugenus, Inc., San Jose, CA (US)

(72) Inventors: Martin J. Salinas, Campbell, CA (US); Miguel Saldana, Santa Cruz, CA (US); Victor Calderon, Santa Clara, CA (US); H. William Lucas, JR., Watsonville, CA (US)

(21) Appl. No.: 18/449,541

(22) Filed: Aug. 14, 2023

Related U.S. Application Data
(60) Provisional application No. 63/371,564, filed on Aug. 16, 2022.

(51) Int. Cl. H01J 37/32

(52) U.S. Cl. CPC H01J 37/3244; H01J 2237/332; H01J 2237/002

(57) ABSTRACT

A temperature-controlled showerhead assembly is configured to deliver a plurality of gases into a cyclic deposition chamber. The showerhead assembly comprises a showerhead body having a cavity formed therethrough and at a central region thereof, wherein the cavity is configured to diffuse or mix the gases prior to introducing the gases into the deposition chamber. The showerhead assembly additionally comprises a network of cooling channels configured to conduct heat away from the showerhead body. The showerhead assembly further comprises a network of heating elements configured to supply heat to the showerhead body, wherein the network of heating elements is disposed closer to the an upper surface of the showerhead body relative to the cooling channels.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the priority benefit under 35 U.S.C. § 119(e) to U.S. Provisional Patent Application No. 63/371,564, filed Aug. 16, 2022, entitled “TEMPERATURE-CONTROLLED SHOWERHEAD ASSEMBLY FOR CYCLIC VAPOR DEPOSITION,” the content of which is hereby expressly incorporated by reference in its entirety.

### BACKGROUND

### Field

The disclosed technology relates generally to thin film deposition systems, and more particularly to showerhead assemblies for cyclic vapor deposition systems.

### Description of the Related Art

As semiconductor devices continue to scale in lateral dimensions, there is a corresponding scaling of vertical dimensions of the semiconductor devices, including thickness scaling of the functional thin films such as electrodes and dielectrics. Semiconductor fabrication involves various thin films that are deposited and patterned throughout the process flow. The thin films employed in semiconductor fabrication can be formed using various techniques, including wet and dry deposition methods. Wet deposition methods include, e.g., aerosol/spray deposition, sol-gel method and spin-coating. Dry deposition methods include physical vapor-based techniques, e.g., physical vapor deposition (PVD) and evaporation. Dry deposition methods additionally include precursor and/or chemical reaction-based techniques, e.g., chemical vapor deposition (CVD) and cyclic deposition such as atomic layer deposition (ALD).

### SUMMARY

In one aspect, a temperature-controlled showerhead assembly configured to deliver a plurality of gases into a cyclic deposition chamber comprises a showerhead body having a cavity formed therethrough and at a central region thereof, wherein the cavity is configured to diffuse or mix the gases prior to introducing the gases into the deposition chamber. The showerhead assembly additionally comprises a network of cooling channels configured to transfer heat away from the showerhead body. The showerhead assembly further comprises a network of heating elements configured to supply heat to the showerhead body, wherein the network of heating elements is disposed closer to an upper surface of the showerhead body relative to the cooling channels.

In another aspect, a temperature-controlled showerhead assembly configured to deliver a plurality of gases into a cyclic deposition chamber comprises a showerhead body having a substantially flat outer surface facing away from a susceptor disposed under the showerhead body while having an inner surface facing the susceptor that is tapered such that a thickness of the showerhead body increases from a central region towards an edge portion thereof. The showerhead assembly additionally comprises a cavity formed through the showerhead body at the central region and configured to diffuse or mix the gases prior to introducing the gases into the deposition chamber. The showerhead assembly further comprises a network of cooling channels and a network of heating elements formed at different vertical levels.

In another aspect, a temperature-controlled showerhead assembly configured to deliver a plurality of gases into a cyclic deposition chamber comprises a showerhead body comprising a cavity formed therethrough and at a central region thereof, wherein the cavity is configured to diffuse or mix the gases prior to introducing the gases into the deposition chamber. The showerhead assembly additionally comprises a network of cooling channels formed over the showerhead body and configured to conduct heat away from the showerhead. The showerhead assembly further comprises a network of heating elements configured to supply heat to the showerhead. The showerhead assembly further comprises a thermally insulating film vertically interposed between the cooling channels and the network of heating elements.

### BRIEF DESCRIPTION OF THE DRAWINGS

FIG. 1 schematically illustrates a thin film deposition system including a deposition chamber configured to deliver a plurality of gases using a temperature-controlled showerhead assembly, according to embodiments.

FIG. 2 shows a perspective view of a top external portion of a thin film deposition system including multiple processing stations each configured for a temperature-controlled showerhead assembly, according to some embodiments.

FIG. 3A illustrates a cross-sectional view of a temperature-controlled showerhead assembly, according to some embodiments.

FIG. 3B illustrates a cross-sectional view of a temperature-controlled showerhead assembly, according to some other embodiments.

FIG. 4 is a partial cross-sectional view of the showerhead assembly illustrated in FIG. 3B, including an expanded view of a diffusing/mixing cavity.

FIG. 5 illustrates a perspective view of a showerhead body of the showerhead assembly illustrated in FIG. 3B.

FIG. 6 illustrates a view of a diffusing/mixing cavity according to embodiments.

FIG. 7 illustrates a result of a computational fluid dynamic analysis performed to illustrate the diffusing and mixing effect in the diffusing/mixing cavity illustrated in FIG. 6.

FIG. 8 is a partial cross-sectional view of the showerhead assembly illustrated in FIG. 3B, including an expanded view of an edge portion of a deposition chamber.

FIG. 9 illustrates an exploded view of a showerhead assembly, according to some embodiments.

FIG. 10 illustrates a substrate-facing surface of a showerhead body of the showerhead assembly illustrated in FIG. 3B, showing locations where temperature sensors are disposed.

FIG. 11 illustrates schematic cross-sectional view of a showerhead assembly, showing cooling channels, a heater, and an insulation layer interposed therebetween.

FIG. 12 illustrates a graph of experimental temperature measurements from a showerhead body, according to some embodiments.

FIG. 13 illustrates one example precursor delivery sequences.

FIG. 14 illustrates an example partial cross-sectional view of a semiconductor structure showing a high aspect ratio feature and step coverage of a thin film.

### DETAILED DESCRIPTION

Cyclic deposition processes such as atomic layer deposition (ALD) processes can provide relatively conformal thin films on relatively high aspect-ratio (e.g., 2:1) structures on substrates (e.g., wafers) with high uniformity and thickness precision. For the context of this disclosure, uniformity means consistency (e.g., consistency of thickness, resistivity, step coverage) of a thin film within the same substrate. While generally less conformal and uniform compared to ALD, thin films deposited using continuous deposition processes such as chemical vapor deposition (CVD) can provide higher productivity and lower cost. ALD and CVD can be used to deposit a variety of different films including elemental metals, metallic compounds (e.g., titanium nitrite (TiN), tantalum nitrite (TaN), etc.), semiconductors (e.g., silicon (Si), III-V, etc.), dielectrics (e.g., silicon dioxide (SiO₂), aluminum nitrite (AlN), hafnium oxide (HfO₂), zirconium oxide (ZrO₂), etc.), rare-earth oxides, conducting oxides (e.g., iridium oxide (IrO₂), etc.), ferroelectrics (e.g., lead titanate (PbTiO₃), lanthanum nickel oxide (LaNiO₃), etc.), superconductors (e.g., Yttrium Barium Copper Oxide (Yba₂Cu₃O₇₋ₓ), and chalcogenides, e.g.), germanium-antimony-tellurium (GeSbTe), to name a few.

Some cyclic deposition processes, such as atomic layer deposition (ALD), include alternatingly exposing a substrate to a plurality of precursors to form a thin film. The different precursors can alternatingly at least partly saturate the surface of the substrate and react with each other, thereby forming the thin film in a layer-by-layer fashion. There are different types of ALD, including time-based ALD and spatial ALD. In a time-based ALD, precursors are injected sequentially, reacting one at a time with active sites on the substrate surface. The exposures to successive precursors may be separated by a purge step in order to prevent mixing and reaction of the successive precursors in the gaseous phase. The reaction is thus surface-limited and self-terminating, yielding uniform deposition. In addition, many ALD processes can allow for deposition of high-quality materials at substantially lower temperatures than with CVD, even near room temperature. ALD growth can take place in a particular temperature range, below which precursor molecules may not be sufficiently activated or desorption can be too slow, and above which precursors can decompose at the surface or even before reaching it, and desorption can be too fast during the purge step. Therefore, temperature control of the deposition chamber is important for high quality thin deposition adopting the ALD processes.

Because of the layer-by-layer growth capability, ALD can enable precise control of the thickness and the composition, which in turn can enable precise control of various properties such as conductivity, conformality, uniformity, barrier properties and mechanical strength. In particular, due to thickness scaling that often accompanies feature size scaling in semiconductor devices, there is an increasing need to improve the within-wafer uniformity even for ALD that is already known to produce thin films with very high uniformity relative to other techniques. Although ALD films generally have excellent uniformity, there may be several reasons why the uniformity could be degraded during deposition. The uniformity could be degraded due to, e.g., overlapping precursor pulses, non-uniform precursor distribution resulted from insufficient mixing and/or diffusion, thermal self-decomposition of precursors, and non-uniformities in substrate temperature, to name a few.

Non-uniform precursor distributions can be caused by limited diffusion or mixing with carrier gases, as mentioned above. For example, in ALD reactors (e.g., deposition chambers formed in processing stations) the precursors are introduced to the deposition or reaction chamber from individual source delivery lines, and the lines may be brought together to a common in-feed line prior to being introduced into the atomic layer deposition (ALD) chamber (e.g., simply deposition chamber). Without being bound to any theory, a carrier gas, which may be flowing through all precursor delivery lines, can sometimes result in the carrier gas from one precursor delivery line serving as a diffusion barrier for the precursor flowing from a different precursor delivery line. Although each precursor would get properly mixed with the carrier gas in the individual source delivery line, the precursor may not properly spread out beyond the intersection of the common chamber in-feed line that is usually located a short distance from the substrate in the upstream direction.

To mitigate these concerns, some processing stations employ a means for distributing precursor/reactant and purge gases within the chamber volume. One such means includes a showerhead employed to effectively distribute and mix gases including precursors. Design variations of this hardware can range from flat designs to tapered designs. Gas distribution can be provided in one of several ways, including (1) across the surface of the showerhead via a plurality of holes supplied by one or more plenums, (2) fed from the center of the showerhead or (3) from one end to the other (also referred to as cross-flow).

In order to reduce the above-noted non-uniformity issues arising from insufficient mixing or diffusion of the gases, some deposition chambers, e.g., chambers with flat showerheads and distributed holes, have a larger spacing between the showerhead and the substrate to increase the mixing and diffusion and reduce the effects of gas impingement on the substrate. However, increased spacing between the showerhead and the substrate comes at a price of longer ALD cycle times due to increased volume to fill with gases and to purge. In time-based ALD, longer time needed to fill and purge the chamber can also worsen the non-uniformity arising from overlapping precursor pulses, because there may be longer leading and trailing edges for precursor pulses. In spatial deposition chambers with flat showerheads, spacing can be smaller but there may also typically a leading and trailing edge effect.

Furthermore, in addition to spatial optimization of the chamber including the spacing between the showerhead and the substrate, spatial and temporal temperature fluctuation at the showerhead can affect various deposition characteristics including thickness non-uniformity causes such as greater. The inventors have found that, for the stringent requirements of today's semiconductor manufacturing specifications, such temperature fluctuation at the showerhead can cause temperature fluctuations at the substrate level, which translates to within-wafer thin film nonuniformities of various parameters, including thickness, resistivity, and step coverage, to name a view.

Thus, there is a need for precursor delivery systems designed for improved productivity (e.g., lower ALD cycle time) and uniformity of the thin films deposited in ALD systems. To address these and other sources of non-uniformities, various embodiments disclosed herein relate to a temperature-controlled showerhead assembly.

Various hardware design considerations for cyclic vapor deposition systems, e.g., ALD deposition systems, are inter-dependent. A design optimization for one parameter can sometimes result in degradation of another parameter. For example, it may be desirable to reduce the volume between a showerhead and the substrate that needs to be filled during an exposure of the substrate to a precursor, such that a shorter amount of time is needed to saturate the substrate surface with the precursor. However, the inventors have discovered that a reduction in the showerhead-to-substrate distance can significantly increase heat transfer between the substrate and the showerhead, thereby detrimentally impacting various properties of the resulting thin films. In particular, the inventors have discovered that a showerhead design for an ALD processing station can have a significant impact on the thickness, composition and physical property uniformity of the thin films deposited in a deposition chamber. Among others, the inventors have discovered that controlling the spatial temperature profile of the showerhead, as well as maintaining a relatively constant temperature thereof, can be important for reducing non-uniformities in the thin films deposited by ALD processes. In addition, the inventors have discovered that adequately diffusing the precursors and/or mixing the precursors with the purge gases prior to their contact with the substrate can be important for the uniformity of the deposited thin films.

To address the above-mentioned needs among others, a cyclic vapor deposition system according to embodiments comprises a deposition chamber configured to deposit a thin film by alternatingly exposing a substrate (e.g., a wafer, a semiconductor element) to a plurality of gases including precursors, wherein the thin film deposition chamber is configured to introduce one or more of the gases into the thin film deposition chamber using a temperature-controlled showerhead assembly. The showerhead assembly according to various embodiments comprises a showerhead body having a gas diffusing/mixing cavity formed therethrough at a central region (e.g., an upper central region) thereof, wherein the diffusing/mixing cavity is configured to receive the gases from external sources and diffuse and/or mixing the precursors prior being introduced into the ALD deposition chamber. The showerhead assembly further comprises a hater (e.g., a network of heating elements) configured to supply heat to the showerhead. The showerhead assembly additionally comprises a network of cooling channels configured to run a coolant therein to carry heat away from the showerhead. The heating elements and the cooing channels are controlled so that the showerhead is kept within a temperature range configured for the thin film being deposited.

In various embodiments, the heating elements are embedded in the showerhead body, e.g., disposed on a top surface of thereof.

In various embodiments, the cooling channels may be formed in a component disposed next to the showerhead body, e.g., in a component immediately thereover.

In various embodiments, the showerhead body has a substantially flat outer surface portion at a distance and away from a susceptor that supports a substrate for thin film deposition. The showerhead body further has a tapered inner surface portion facing the susceptor. The inner surface portion is connected with the outer surface portion, and the tapering makes the inner surface portion further away from the susceptor closer to the center of the susceptor.

In various embodiments, the gas diffusing/mixing cavity is a cone-shaped gas diffusing and/or mixing cavity.

In various embodiments, the heater (e.g., network of heating elements) and the network of cooling channels are formed at different vertical levels and configured such that during a deposition, the inner surface of the showerhead body is maintained at a temperature that is at least 20° C. higher than a temperature of the coolant flowing the cooling channels.

In various embodiments, the showerhead assembly further comprises a thermal insulation film interposed between the cooling channels and the heating elements and configured to limit heat transfer therebetween.

The temperature-controlled showerhead assembly allows, among other things, improvements in temperature control of the showerhead and in turn in temperature of the substrate, as well as spatial uniformity of the precursor delivered to the substrate surface, which in turn allows for improvements in the resulting thin film characteristics, e.g., improved thickness and composition uniformity. When the deposited thin film is a conductor, e.g., TiN, the system additionally allows for improved resistivity uniformity. The system additionally improves step coverage of the thin films in high aspect ratio structures on the substrate.

In the following discussions, embodiments may be described using specific precursors for specific films by way of examples. For example, specific example precursors including titanium tetrachloride (TiCl₄), ammonia (NH₃) and dichlorosilane (SiCl₂H₂) for depositing TiN and/or titanium silicon nitride (TiSiN) may be used to describe the thin film depositions and methods of depositing such thin films according to various embodiments. However, it will be understood that embodiments are not so limited, and the inventive aspects can be applied to any suitable combination of precursors for depositing any suitable thin film that can be formed using cyclic deposition processes, such as the ALD process.

### Cyclic Thin Film Deposition System

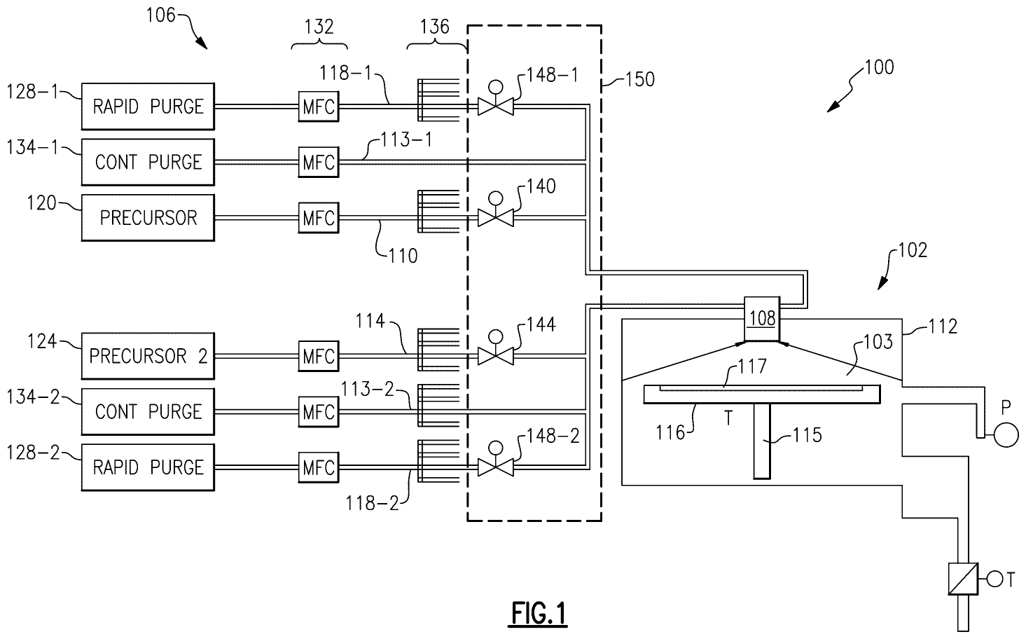

FIG. 1 schematically illustrates a thin film deposition system 100 including a deposition chamber 103 configured to deliver precursors using a temperature-controlled showerhead assembly 112, according to embodiments. The thin film deposition system 100 includes a thin film processing station 102 having the deposition chamber 103 formed therein. A precursor delivery system 106 is configured to deliver a plurality of precursors into the deposition chamber 103. The illustrated deposition chamber 103 is configured to form a thin film on a substrate 117 disposed on a support (e.g., susceptor) 116, which is coupled to a supporting post 115, under a process condition. The deposition chamber 103 additionally includes an injector block 108 coupled to an upper central portion of the deposition chamber 103 and configured to centrally discharge the plurality of precursors into the deposition chamber 103 through the temperature-controlled showerhead assembly 112, which forms a boundary of the deposition chamber 103. The injector block 108 may channel the gases, e.g., a precursor and a purge gas, into a gas diffusing cavity prior to being introduced into the deposition chamber 103 to contact the substrate 117. The temperature-controlled showerhead assembly 112 is configured to uniformly distribute the precursor(s) over the substrate 117 held on the susceptor 116 so that a uniform film deposition occurs. The deposition chamber 103 may be equipped with a pressure monitoring sensor (P) and/or a temperature monitoring sensor (T).

The precursor delivery system 106 is configured to deliver a plurality of precursors from precursor sources (120, 124) and one or more purge gases, e.g., inert gases, from purge gas sources (128-1, 128-2, 134-1, 134-2) into the deposition chamber 103. Each of the precursors and purge gases is connected to the deposition chamber 103 by a respective gas delivery line. The gas delivery lines additionally include in their respective paths mass flow controllers (MFCs) 132 and precursor valves for introducing respective precursors and purge gases into the thin film deposition chamber 103. Further advantageously, at least some of the valves can be ultrafast atomic layer deposition (ALD) valves.

For illustrative purposes only, in the illustrated configuration of FIG. 1, the plurality of precursors include a first precursor and a second precursor. The first precursor is stored in at least one first precursor source 120, and the second precursor is stored in at least one second precursor source 124. The precursor delivery system 106 is configured to deliver the first and second precursors from the first and second precursor sources 120, 124 into the deposition chamber 103 through first and second precursor delivery lines 110, 114, respectively. A rapid purge (RP) gas can be stored in at least two RP gas sources 128-1, 128-2. The precursor delivery system 106 is configured to deliver the rapid purge (RP) gas from the RP gas sources 128-1, 128-2 into the deposition chamber 103 through respective ones of RP gas delivery lines 118-1, 118-2. A continuous purge (CP) gas can be s stored in at least two CP gas sources 134-1, 134-2. The precursor delivery system 106 is configured to deliver the CP gas from the CP gas sources 134-1, 134-2 into the deposition chamber 103 through respective ones of CP gas delivery lines 113-1, 113-2.

The first and second precursors are configured to be delivered from the first and second precursor sources 120, 124, respectively, by independently actuating first and second precursor ALD valves 140, 144 that are connected in parallel before the processing station 102. Additionally, the RP gas is configured to be delivered from the RP purge gas sources 128-1, 128-2 by independently actuating two respective purge gas ALD valves 148-1, 148-2 that are connected in parallel before the processing station 102. The ALD valves 140, 144, 148-1 and 148-2 and the respective delivery lines connected to the processing station 102 can be arranged to feed the respective gases into the injector block 108 through a multivalve block assembly, which may be attached to a lid portion of the processing station 102. In the illustrated configuration, the ALD valves 140, 144, 148-1 and 148-2 are final valves before the respective gases are introduced into the deposition chamber 103 of the processing station 102.

By way of example only, the first and second precursors can include TiCl₄ and NH₃, respectively, that are delivered into the deposition chamber 103 from respective TiCl₄ and NH₃ sources through respective precursor delivery lines to form a thin film (e.g., TiN thin film). The precursor delivery system 106 can additionally be configured to deliver argon (Ar) as the purge gas into the processing chamber 103 from Ar sources through purge gas delivery lines. Purge gases may be delivered as a continuous purge (CP) gas, and/or as a rapid purge (RP) gas, which may be delivered through dedicated purge gas ALD valves as shown in FIG. 1. The CP gas may be introduced with one of the precursors, and may be mixed in a vertical cavity formed through a showerhead block of the showerhead assembly 112, before being introduced into the main deposition chamber 103. The illustrated precursor delivery system 106 can be configured to deliver Ar as an RP gas into the process chamber 103 from the purge gas sources 128-1, 128-2 through respective purge gas delivery lines and purge gas ALD valves 148-1, 148-2. The CP gases may be delivered to the deposition chamber 103 without a purge gas ALD valve. Such CP gases may serve as carrier gases and be introduced into the injector block 108 simultaneously with precursors.

According to various embodiments, the thin film deposition system 100 may be configured for a thermal ALD deposition without an aid of plasma. While plasma-enhanced processes such as plasma enhanced atomic layer deposition (PE-ALD) process may be effective in forming conformal films on surfaces with features having relatively low aspect ratios, such processes may not be effective in depositing films inside vias and cavities of a substrate with features having relative high aspect ratios. Without being limited by theory, one possible reason for this is that a plasma may not reach deeper portions of high aspect ratio vias under some circumstances. In these circumstances, different portions of the vias may be exposed to different amounts of the plasma, leading to undesirable structural effects arising from non-uniform deposition, such as thicker films being deposited near the opening of the via compared to thinner films being deposited at deeper portions (e.g., sometimes called cusping or keyhole formation). For these reasons, a thermal cyclic vapor deposition such as thermal ALD deposition may be more advantageous, because such thermal processes have weak dependence on the ability of the plasma to reach different portions of the surface being deposited on.

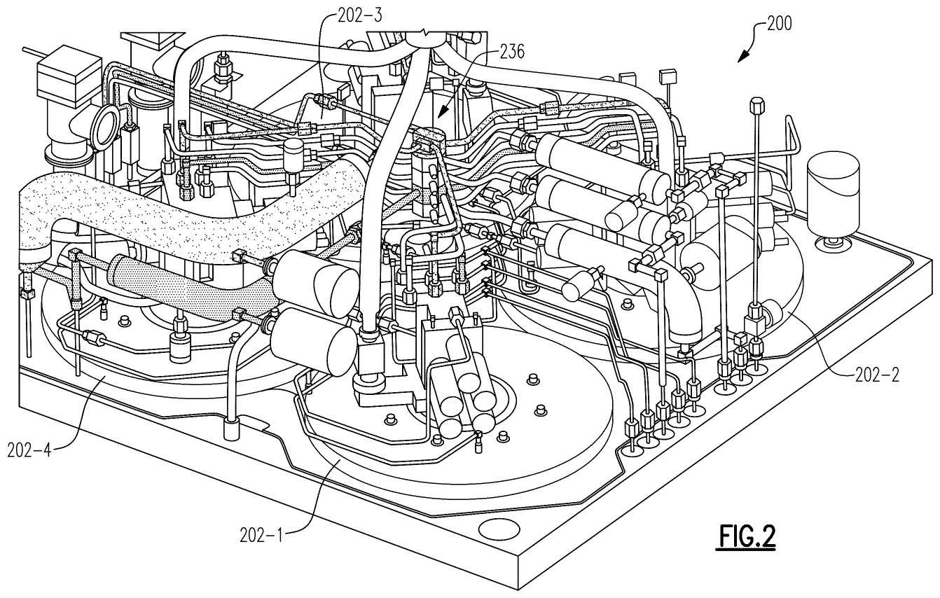

FIG. 2 shows a perspective view of a thin film deposition system 200 comprising a plurality of processing stations (e.g., four processing stations). Each of the plurality of processing stations is configured to form a thin film on a substrate disposed in a deposition chamber from a plurality of precursors delivered therein under unique process conditions, including a process temperature, a process pressure. In some embodiments, the plurality of processing stations share the same process condition when the same thin film is formed at each station. In the illustrated embodiment, there are four processing stations, 202-1, 202-2, 202-3, 202-4, having corresponding showerhead assemblies. The processing stations 202-1, 202-2, 202-3, 202-4 can be, e.g., single substrate processing stations each configured to deposit one or more precursors through respective precursor delivery lines. While the illustrated deposition system 200 is a multi-station process system, it will be appreciated that the embodiments disclosed herein are not limited thereto, and can be implemented in any suitable single wafer or multi-wafer process chambers.

As described with respect to FIG. 1, the deposition system 200 may include a plurality of gas (e.g., precursor, purge gas) deliver lines configured to deliver precursors and purge gases to the plurality of processing stations. In FIG. 2, each of the delivery lines may start from a source, connecting to an MFCs, a manifold 236 where the precursor or purge gas delivery lines may branch off and send the corresponding gas to the different processing stations 202-1, 202-2, 202-3, 202-4. Before reaching the respective processing station, each branched off delivery line may be connected to an ALD valve to precisely turn on and off the delivery line to deliver the corresponding precursor or purge gas to the connected processing station. It is to be noted that a CP gas line may not need the ALD valve as is thus continuous delivered to the connected processing station. When delivered together with a precursor, this CP gas serves as a carrier gas. According to FIG. 1, each of the processing stations 202-1, 202-2, 202-3, 202-4 shown in FIG. 2 includes therein a showerhead assembly 112 having an injection block 108 cyclically delivering a plurality of precursors and purge gases into a deposition chamber 103 and on to a substrate 117 which is disposed on a susceptor 116.

The example embodiment deposition system 200 as shown in FIG. 2 can particularly benefit from various combinations of embodiments disclosed herein, including high conductance line portions and ALD valves, such that exposures to each precursor can be substantially shortened without sacrificing desirable film characteristics such as conformality, step coverage and station-to-station consistency.

### Showerhead Assembly

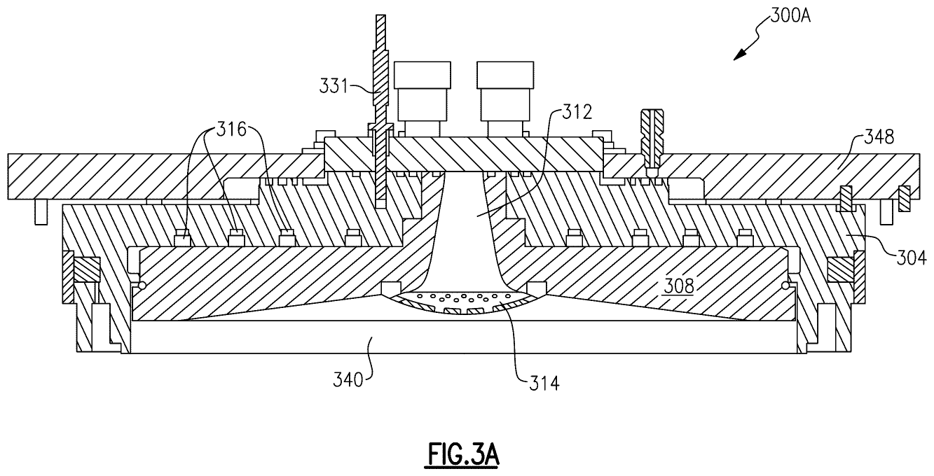

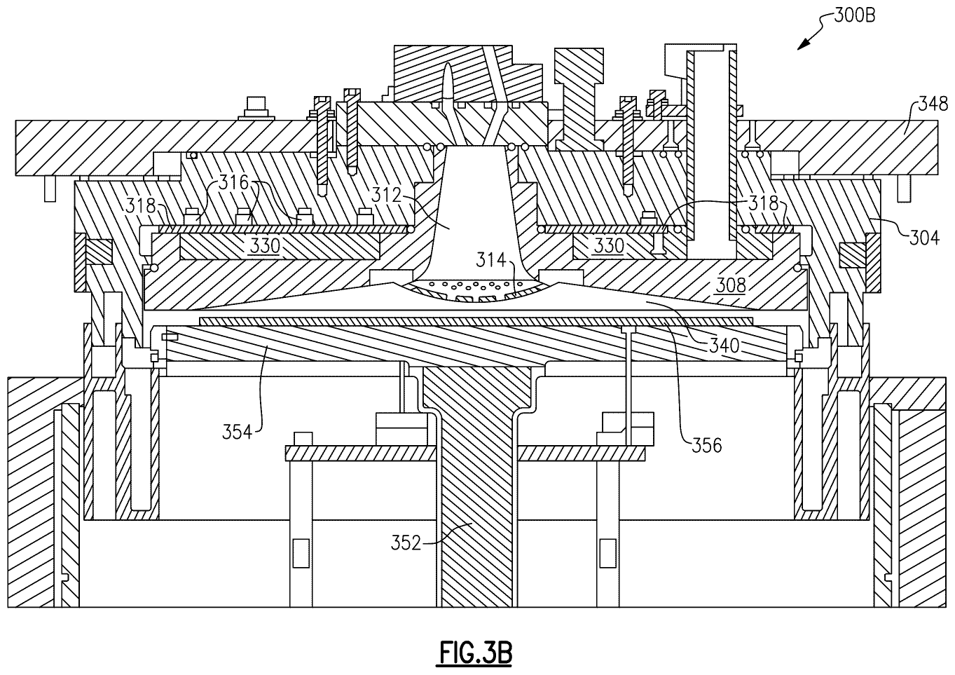

FIG. 3A illustrates a cross-sectional view of a temperature-controlled showerhead assembly 300A, according to some embodiments. The showerhead assembly 300A comprises a center-feed showerhead body 308, which may be formed of a highly thermally conductive material, such as a metallic material, e.g., aluminum. The showerhead body 308 has a gas diffusing/mixing cavity 312 formed in/through an upper central region thereof to accept the delivered precursors and purge gases into the diffusing/mixing cavity 312. The gas diffusion and/or mixing effect is described elsewhere herein. In the lower portion of the showerhead body 308 a deposition chamber 340 is disposed, where the precursors and purge gases are introduced into and deposition of a thin film on a substrate takes place. Between the upper diffusing/mixing cavity 312 and the lower deposition chamber 340, an optional perforated plate 314 may be disposed to fluidically connect the diffusing/mixing cavity 312 above and the deposition chamber 340 below and to restrict and more uniformly distribute the gases flowing therethrough from the diffusing/mixing cavity 312 and into the deposition chamber 340. The showerhead assembly 300 may additionally comprise a network of cooling channels 316 formed above the showerhead body 308. The cooling channels 316 can be arranged in a suitable pattern, e.g., a plurality of concentric radial rings, a serpentine pattern, etc., to cover an upper surface of the showerhead body 308. The network of cooling channels 316 may be configured to be connected to a heat exchanger (not shown) and have a coolant flowing therein to carry out heat from the showerhead body 308. The showerhead assembly 300A may further comprise temperature sensors 331 to measure a temperature of the showerhead body 308.

FIG. 3B illustrates a cross-sectional view of another embodiment of a temperature-controlled showerhead assembly 300B. The showerhead assembly 300B incorporates, among other design parameters, various design improvements over the showerhead assembly 300A as described above with respect to FIG. 3A. The showerhead assembly 300B comprises various features that are similar to those of the showerhead assembly 300A, the details of which may not be repeated herein for brevity. For example, a showerhead body 308 which is made of a thermally conductive material (e.g., metal) forms an upper gas diffusing/mixing cavity 312 and a lower deposition chamber 340 with a perforated plate 314 disposed therebetween. The perforated plate 314 may be disposed to fluidically connect the diffusing/mixing cavity 312 to the deposition chamber 340 and to restrict and more uniformly distribute the gases from the diffusing/mixing cavity 312 into the deposition chamber 340. The showerhead body 308 is configured to receive and distribute the precursors and purge gases into the thin film deposition chamber 340 through the gas diffusing/mixing cavity 312.

The showerhead assembly 300B also has a plurality of cooling channels formed above the showerhead body 308. In addition, the showerhead assembly 300B shown in FIG. 3B has a heater 330 disposed between showerhead body 308 and the cooling channels 316. The heater 330 may be implemented in contact with the showerhead body 308. The heater 330 can be a single piece or a plurality of heating elements (e.g., a network of heating elements) arranged in a pattern (e.g., ringed or serpentine pattern). An insulation layer 318 may be disposed between the cooling channels 316 and the heater 330 to limit heat transfer from the heater 330 to the cooling channel 316. The cooling channel 316, the insulation layer 318 and the heater 330 may be configured to control the temperature of the showerhead body 308, as further described elsewhere herein.

As shown in FIGS. 3A and 3B, a housing 304 encapsulates the showerhead body 308 and fills the volume between a lid portion 348 that forms a top cover of the showerhead assembly 300 and the showerhead body 308. As can be seen in FIG. 3B, the network of cooling channels may be formed in the portion of the housing 304 that is above the showerhead body 308. The housing 304 forms an outer circumferential wall of the deposition chamber 340. As illustrated in FIG. 3B, below the deposition chamber 340 a susceptor 354 is disposed to hold a substrate, and is coupled to a support post 352 below. A top surface of the susceptor 354 is configured to hold a substrate (e.g., a wafer) 356 for thin film deposition. The circumferential wall of the housing 304 is connected to structures that surrounds the susceptor 354 and the supporting post 352. The connection between the circumferential wall 304 and the surrounding structures of the susceptor 354 may form hermetical seal so that the deposition chamber 340 is fluidically separated from the outer environment.

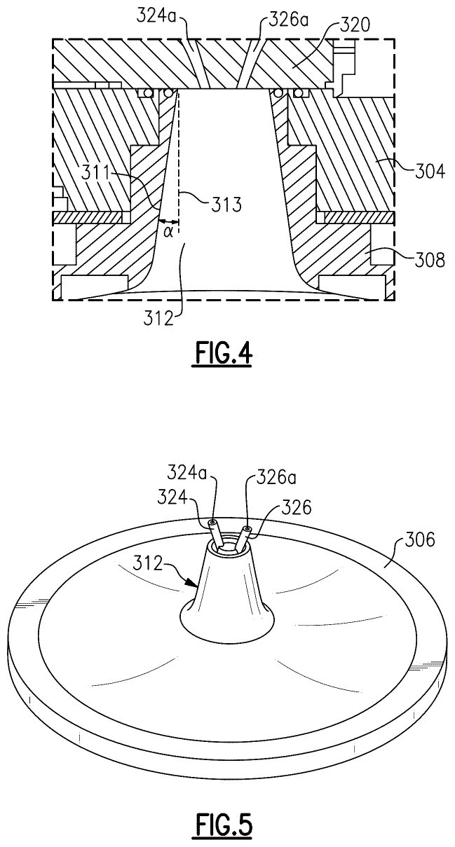

The inventors have discovered that a few factors related to the structure of the showerhead body 308 are important to determine the flow pattern of the precursors in the deposition chamber 340 and the quality (e.g., uniformity) of thin film deposition. FIG. 4 is a partial cross-sectional view taken from the cross-sectional view of FIG. 3B to illustrate the diffusing/mixing cavity 312 located at the upper center of the showerhead body 308. As shown in FIG. 4, the diffusing/mixing cavity 312 may be cone shaped having a steep tapered sidewall 311, with a diameter of the widest bottom portion of the cone smaller than a height. The diameter of the bottom portion of the diffusing/mixing cavity 312 can be 20 mm, 30 mm, 40 mm, 50 mm, 60 mm, 70 mm, 80 mm, 90 mm, 100 mm, or a value in range defined by any of these values. A first cone angle α between the tapered sidewall 311 of the diffusing/mixing cavity 312 and a vertical line 313, which is perpendicular to the top surface of the susceptor 354. According to some embodiments, the cone angle α can be less than 12°, 10°, 8°, 6° or a value in a range defined by any of these values, for instance 4.5°. The inventors have found that the steep tapered sidewall 311 can be critical for advanced semiconductor applications, as described further elsewhere herein.

Referring to FIG. 4, the showerhead body 308 further incorporates an injector block 320, located in an upper portion of the diffusing/mixing cavity 312. The diffusing/mixing cavity 312 is connected with inlet channels 324a and 324b and configured to receive the inlet precursors and purge gases therethrough.

The inventors have found that the arrangement of gas inlet channels defined inside the injector block can be an important implementation for uniform distribution of precursors and purge gases. In particular, the inventors have discovered that, when the inlet gas channels are arranged to extend in a vertical direction, the resulting distribution of gases incident on the substrate (e.g., substrate 356 shown in FIG. 3B) may undesirably be concentrated about a line-of-sight position, e.g., a central portion of the substrate. Without being bound to any theory, this phenomenon may be because a velocity profile of a jet flow from a vertically arranged inlet channel is normally parabolic shaped with higher velocity in the central region and lower velocity toward a side of the jet. In this way, the flow may be primarily downward impinging on the central portion of the substrate with limited sideway flow and diffusion. If a precursor is dispensed with a carrier gas and is locally concentrated the inlet channel, the limited diffusion and mixing may result in nonuniform distribution when the fluid with the precursor reaches the substrate. To address this concern, in the illustrated example design, the inlet gas channels 324a and 324b of the injector block 320 extend in substantially off-vertical and oblique angles, as can be seen in FIG. 4.

FIG. 5 is a perspective view of an embodiment of the showerhead body 308 with the outer wall of the diffusing/mixing cavity 312 rising from the top surface thereof. Two inlet tubes 324 and 326 having the inlet channels 324a and 324b formed therein, respectively, may be coupled to the top portion of the diffusing/mixing cavity 312. As can be seen, the inlet tubes 324 and 326 are angled with a vertical axis that is perpendicular to the top surface of the showerhead body 308.

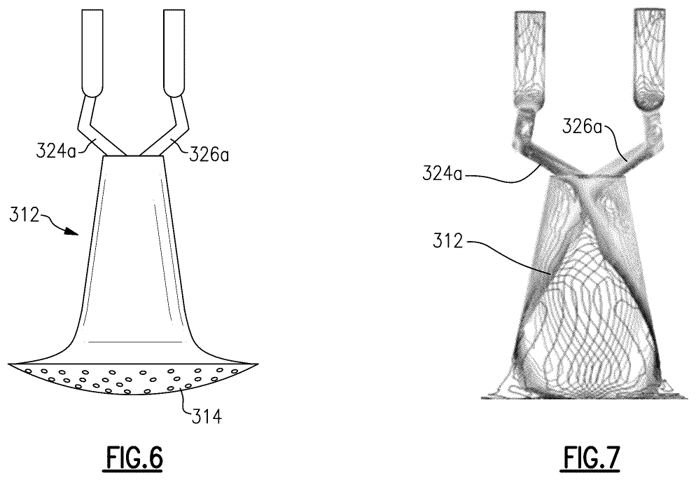

In FIG. 6, the diffusing/mixing cavity 312 and the connected inlet channels 324a and 326b are constructed for computational fluid dynamics (CFD) simulation purpose. The diffusing/mixing cavity 312 is bounded at the lower end by the perforated plate 314. An CFD simulation result related to the configuration shown in FIG. 6 is illustrated in FIG. 7, which shows flow lines of a fluid (e.g., a precursor or purge gas) entering the top end through the inlet channels 324a and 326b. As can be clearly seen in the simulated flow line trajectories, the angled or slanted inlet channels 324a and 326b cause the gaseous fluid to enter the mixing cavity 312 from the top angularly and collide at least once with the sidewall thereof. This colliding may cause eddies and turbulence to form in the fluid and therefore enhances mixing and diffusion, and can result in more uniform precursor dispensing in the gaseous fluid when entering into the deposition chamber below.

As shown in FIGS. 3A, 3B, and 6, downstream from the diffusing/mixing cavity 312 is the perforated plate 314, which has a plurality of perforated holes formed therethrough. The perforated holes may have the same size or different sizes. The perforated holes may restrict the flow and allow the precursors and purge gases to pass more uniformly through each one of them, thereby more uniformly distributing the gases to the deposition chamber 340 downstream of the perforated plate 314.

FIG. 8 is a partial cross-sectional view taken from FIG. 3B to illustrates more details of an edge portion of the deposition chamber 340. As can be seen the deposition chamber 340 is bounded by a tapered lower surface of the showerhead body 308 at the upper side and an upper surface of the susceptor 354 at the lower side. The lower surface of the showerhead body 308 is shallowly tapered, forming a second cone angle β between the tapered lower surface and a plane that is parallel to the upper surface of the susceptor 354 (or the substrate 356). The inventors have found that, relative to a showerhead boy 308 having a flat surface facing the substrate 356, the showerhead body 308 with tapered lower surface allows for a substantial reduction of the volume of the deposition chamber 340. In addition, the inventors have found that the tapered volume of the deposition chamber 340 allows for more uniform flux of gases to be incident on the substrate surface. According to various embodiments, the second cone angle β may be less than 12°, 10°, 8°, 6°, 4° or a value in a range defined by any of these values, for instance 9.0°. It is appreciated by a skilled artisan in the field, a smaller second cone angle β is corresponding to a reduced volume for the deposition chamber 340. The reduction in volume in turn allows for faster cycle time in part due to shorter time that may be needed for purging the volume of unreacted precursor gases between precursor pulses.

Another factor considered is the wafer-to-showerhead body gap S shown in FIG. 8, which is between the lowest portion of the showerhead body 308 and the upper surface of the substrate (e.g., wafer) 356 disposed on the susceptor 354. According to embodiments, the gap S is less than 0.3″, 0.25″, 0.2″, 0.15″, 0.10″ or a value in a range defined by any of these values, for instance 0.15″. The inventors have found that, relative to the gap S of 0.25″, the gap S of 0.15″ or 0.10″ can reduce the volume that of volume of the deposition chamber 340 that is between the showerhead and the substrate by 36% and 45%, respectively. A smaller gap S may also help improve thin film deposition uniformity on the substrate 356. The precursors may be configured to be drained from the gap S surrounding the substrate 356. A smaller gap S may create more fluid resistance and ensures that the precursors to flow more uniformly in all radial directions toward the circumferential edge. It's important for the gap S to have a substantially narrow tolerance range especially when the gap S is small.

### Temperature Control of the Showerhead Assembly

As described above, to enhance the temperature control and response of the showerhead assembly, the showerhead assembly according to embodiments comprises a network of cooling channels and a network of heating elements. The inventors have discovered that the temperature control and response are particularly effective when the cooling channels and heating elements are formed at different vertical levels. In particular, the inventors have discovered that it is advantageous to dispose the network of heating elements closer to an upper surface of the showerhead body relative to the cooling channels. Furthermore, in some implementations, showerhead assembly further comprises a thermally insulating film vertically interposed between the cooling channels and the network of heating elements. The arrangements enables, among other things, improved control of the temperature difference vertically across the showerhead body, as well as faster temporal response thereof.

CFD simulations have been conducted to optimize the design parameters and features of the deposition chamber 340, such as the design factors delineated above with respect to FIGS. 3A-8. The design parameters/features may include the first cone angle α, the second cone angle β, and the gap S. Especially under certain assumptions, CFD simulations have been performed to optimize precursor concentration uniformity and flow velocity distribution on the substrate related to the first cone angle α, and found out that a first cone angle less than 10° is substantially better than a first cone angle of 11°. For the second cone angle β, simulation results show that the precursor concentration is the most uniform when the second cone angle is about 5.5°, while the velocity distribution is the best when the second cone angle is about 6.5°. As to the wafer-to-showerhead body gap S, the simulation results show that the concentration and velocity distribution show substantial improvement when the gap S is about 0.158″ compared to 0.258″. CFD simulations were also performed to compare different implementations of injector blocks. The following table illustrates an example CFD simulation result comparison in terms of deposition chamber volume reduction:

| | Before | | |
|---|---|---|---|
| Factor | Optimized | Optimal | Note |
| First Cone | 10° | <10° | less reduction |
| Angle α | | | beyond 10° |
| Second Cone | 7° | 4.5° | 13% volume |
| Angle β | | | reduction |
| Gap S | 0.258″ | <0.158″ | 36% volume |
| | | | reduction |

### Temperature Control of the Showerhead Body

Besides the structural factors considered above with respect to FIGS. 3A-8 associated with uniformity of gas delivery onto the substrate and the volume of the deposition chamber 308, the inventors have discovered that controlling the temperature of the showerhead body 308 can be important for controlling the uniformity of the deposited thin film both in thickness and physical properties including chemical composition and resistivity.

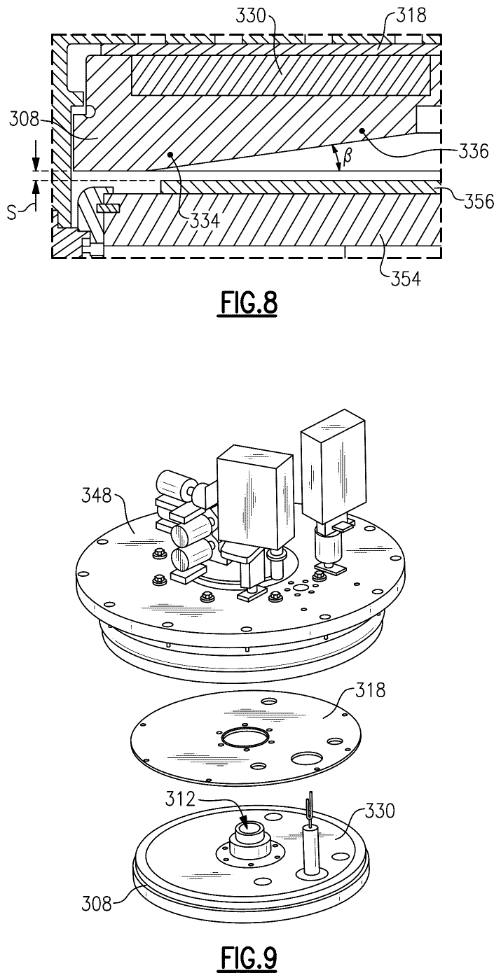

Referring back to FIG. 3B, the susceptor 354 may include a heater embedded therein to heat the substrate 356 in the deposition chamber 340. The heat from the substrate 356 may be transferred to the lower surface of the showerhead body 308, e.g., by radiation and convection to a less extent. On the upper side of the deposition chamber 340, the temperature of showerhead body 308 can be controlled by the combination of the heater 330 coupled to an upper portion of the showerhead body 308, the plurality of cooling channels 316 disposed above the showerhead body 308, and the insulation layer 318 interposed between the cooling channels 316 and the heater 330. In this way the temperature in the deposition chamber 340 can be controlled for optimal thin film deposition. FIG. 9 is an exploded perspective view of the showerhead assembly 300B further illustrating the relationship of the heater 330, the insulation layer 318 and the showerhead body 308. The cooling channels 316 are embedded in the top part of the exposed view and are not visible in the viewing angle.

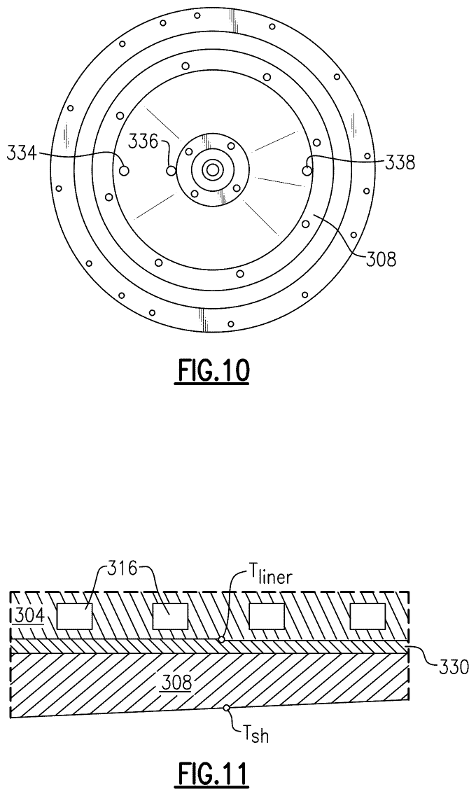

Moving to FIG. 10, the showerhead assembly 300B further comprises temperature sensors 334, 336, and 338 located at different locations having different distances from the center, as viewed in the top view direction. Contrary to the temperature sensor 331 shown in FIG. 3A, which is embedded into the upper portion the housing 304 of the showerhead assembly 300A, the temperature sensors 334, 336, 38 are embedded in the showerhead body 308 of the showerhead assembly 300B. As described above, the showerhead body 308 may be made of a highly conductive material, e.g., aluminum. As such a temperature distribution within the showerhead body 308 can be within a narrow range. The inventors have discovered that the temperature sensors 334, 336, 338 embedded within the solid showerhead body 308 formed of a highly conductive material can optimize the response time of the temperature sensing. The inventors further discovered that, for closed loop temperature control with fast response time, the temperature sensors 334, 336, 338 may be embedded within 0.5″, 0.3″, 0.1″ from the lower surface of the showerhead body 308 facing the substrate 356, or a distance in a range defined by any of these values, to about 0.1″ above the tapered lower surface facing the substrate 356. In the partial cross-sectional view of FIG. 8, the locations of two such temperature sensors are indicated by the numerals 334 and 336.

As described above, it may be desired to control the temperature of the deposition chamber 340 (e.g., the lower surface thereof) within a certain temperature range for depositing a specific thin film. In particular, controlling the temperature of the showerhead body 308 within a temperature range can be important for several reasons in maintaining temperature control during deposition of the thin film on the substrate. For example, if the temperature of the showerhead is too low, undesirable deposition may occur on the surface thereof. Such deposition may cause, among other things, changes in surface emissivity of the showerhead and particle generation. On the other hand, if the temperature is too high, secondary heating of the substrate may occur by radiation. Analyses have been performed to guide in the design of the temperature control system and heat transfer solutions for the showerhead body 308.

FIG. 11 shows a partial cross-sectional view illustrating certain heat transfer components connected to the showerhead body 308 (FIGS. 3A and 3B) including the network of cooling channels 316. As described above, the network of cooling channels 316 formed in the upper portion of the housing 304 over the showerhead body 308 are configured to carry heat away from the showerhead body 308. The cooling channels 316 are configured to flow therein a coolant at a fixed temperature circulated by a heat exchanger (not shown), such that the upper surface of the showerhead body 308 adjacent the cooling channels 316 is kept at a relatively constant temperature. For example, the coolant can be kept at about 100° C., 120° C., 140° C., 160° C., 180° C., 200° C., 220° C. or a temperature in a range defined by any of these values. The temperature of the coolant is determined by the thin film to be deposited and the process configured to deposit the thin film in the deposition chamber 340.

In FIG. 11, the temperature at the lower surface of the housing 304 which makes contact with the showerhead body 308 is designated as Tₗᵢₙₑᵣ. For analysis purposes, the temperature Tₗᵢₙₑᵣ can be considered constant. By way of one example, using known or estimated values of contact thermal resistance between the housing 304 and the upper surface of the showerhead body 308, e.g., R_{contact}, and the thermal resistance of the showerhead body 308, e.g., R_{A1}, the heat transfer rate from the lower surface of the showerhead body 308 to the lower surface of the housing 304 to maintain the illustrated temperature, e.g., Tₛₕ, at the lower surface of the showerhead body 308 can be calculated. The calculation revealed that, to maintain a temperature difference (e.g., ΔT) exceeding 100° C. between the wafer-facing lower surface of the showerhead body 308 and the lower surface of the housing 304 (ΔT=Tₛₕ−Tₗᵢₙₑᵣ), an amount of heat transfer rate needed is exceeding 30,000 W, which is an order of magnitude higher than typical power supplied for the heating power supplied to a semiconductor processing chamber. Conveniently in the industry, power supply for a deposition chamber 340 may be generally as high as 750 W. Applying the quantity of 750 W in the equation that produced the above heat transfer rate of 30,000 W and adopting the same assumptions, calculations revealed that a temperature difference, ΔT, expected is merely about 4 degrees. This temperature difference across the thickness of the showerhead body from a heat transfer rate of 750 W is too narrow to support effective temperature control for the showerhead body 308 for the purpose of maintaining the temperature of the deposition chamber 340.

The calculations carried out as described above illustrate a need for thermal engineering of the showerhead assembly 300A shown in FIG. 3A in the vertical stack direction in order to improve the efficiency of closed loop temperature control of the showerhead body 308. The inventors have discovered that this need arises in part because of the high thermal conductivity of the aluminum material. As discussed below, the inventors have further discovered that introducing a series thermal resistances in the vertical direction according to embodiments can improve the thermal performance. As illustrated in FIGS. 3B, 9, and 11, the insulation later 318 is interposed between the housing 304 and the showerhead body 308 for the purpose of introducing additional series thermal resistance.

The inventors have discovered that controlled thermal isolation between the housing 304 and the showerhead body 308 can be critical in maintaining a substantial temperature difference ΔT, e.g., 10° C., 20° C., 30° C., 40° C., 50° C. or a temperature difference in a range defined by any of these values, and maintaining a narrow temperature range at the lower surface of the showerhead body 308 during a deposition operation. For effective thermal isolation, in addition to physical separation, the inventors have discovered that insertion of an appropriate insulation layer (e.g., the insulation layer 318) can be effective. The insulation layer 318 serves to slow down heat transfer by causing a substantial temperature across the thickness thereof.

The basic heat transfer analysis model used above involving a series of thermal resistances is used for analysis. In addition to the contact thermal resistance (R_{contact}) and the thermal resistance within the showerhead body 308 (RAI), an additional thermal resistance arising from the insulation layer 318 was added into the heat transfer model. As configured, the lower surface of the showerhead body 318 can be maintained at a temperature that is at a suitable temperature, e.g., at least 20° C. higher than a temperature of a liquid coolant circulating the cooling channels 316. The inventors have found that the insulation layer 330 can be a suitable polymer film having a thermal resistance similar to that of polyetheretherketone (PEEK). It has been observed that, using a layer of PEEK for the insulation layer 318, a ΔT of 40° C. between the lower surface of the showerhead body 308 and the lower surface of the housing 304 can be maintained, and a large portion of the 40° C. is across the PEEK insulation layer 318.

As described above with respect with FIG. 3B, as part of the solution to maintain the showerhead body 308 at a desired temperature range for depositing various types of thin films, a heater 330 may be coupled to the upper portion of the showerhead body 308 to supply heat energy to heat up the showerhead body 308. The heater 330 can be a network of heating elements arranged to cover a large area of the upper portion of the showerhead body. 308. The heater 330 can be configured to supply a power of 250 W, 500 W, 750 W, 1000 W, 1250 W, 1500 W, 1750 W, 2000 W, or a power in a range defined by any of these values. For the embodiment shown in FIG. 3B, assuming that the heater 330 is configured to supply a maximum power of 750 W, and the lower surface of the showerhead body 308 can receive up to, e.g., 500 W from the deposition chamber 340 and the substrate 356 below, e.g., through radiation, calculation using the above mentioned heat transfer model revealed that a thickness of 0.029″ (0.7 mm) for the insulation layer 318 (e.g., a layer of PEEK) can maintain a suitable ΔT, e.g., 40° C., between the lower surface of the showerhead body 308 and the lower surface of the housing 304. It may be desirable to maintain the ΔT of 40° C. using a smaller power supply. In some embodiments, assuming that the maximum radiation from the substrate 356 and the deposition chamber 340 stays at 500 W, and a maximum power supply of 250 W is used for closed loop control of temperature Tₛₕ at the lower surface of the showerhead body 308, calculation revealed that a thickness of 0.055″ (1.4 mm) of the insulation layer 318 may be effective. Either a thickness of 0.029″ or a thickness of 0.055″ is a small thickness.

Using the heater 330 and the network of cooling channels 316 with the insulation layer 318 interposed therebetween, and the temperature sensors 334, 336, 338, the showerhead assembly 300 can be configured with a closed loop temperature control system for maintaining the lower surface of the showerhead body 308 at relatively small temperature range during a thin film deposition operation in the deposition chamber 340. Thus configured, the network of cooling channels 316 and the heater 330 disposed at different vertical levels and in thermal communication with each other and with the showerhead body 308 are controlled together. As such, the temperature of the lower surface of the showerhead body 308 facing the substrate 356 is maintained at a temperature that is at least 20° C. higher than the temperature of the lower surface of the housing 304 or the liquid coolant circulating the cooling channels 316 during the operation. In some embodiments, the temperature of the lower surface of the showerhead body 308 can be maintained at least 40° C. higher than the temperature of the liquid coolant circulating the cooling channels 316. Depending on the temperature of the coolant running in the coolant channels 306, the lower surface of the showerhead body 308 can be maintained at a mean temperature of 120° C., 140° C., 160° C., 180° C., 200° C., 240° C., or a temperature in a range defined by any of these values, for instance in the range of 160° C.-230° C. during deposition of a thin film on the substrate 356, which can be at a temperature above 300° C., 350° C., 400° C., 450° C., 500° C., 600° C., 650° C., or a temperature in a range defined by any of these values.

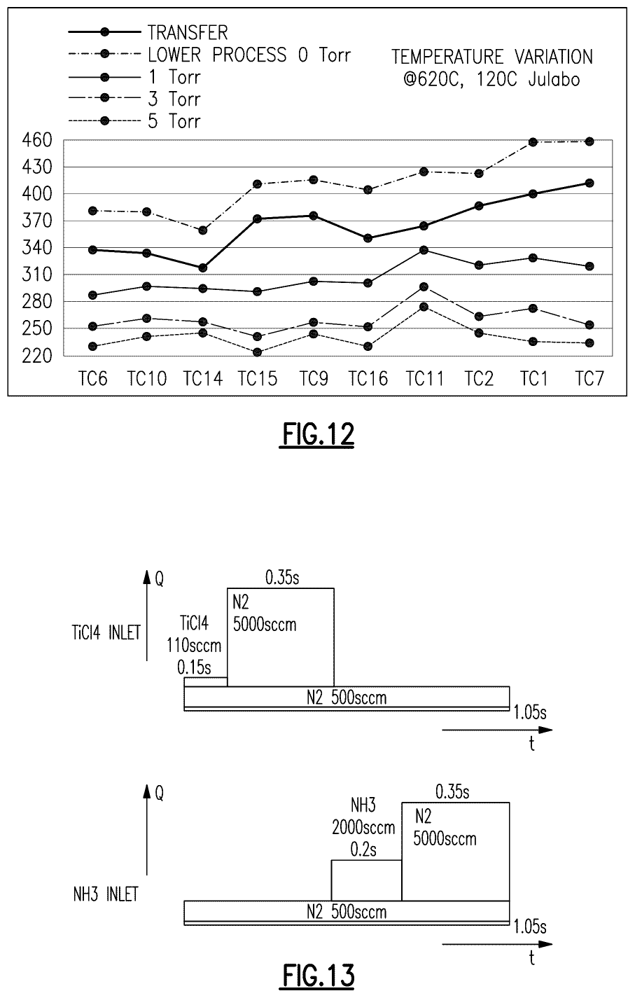

FIG. 12 illustrates temperature measurements at the lower surface of the showerhead body 308. It can be seen that the within-showerhead body temperature can be maintained at a relatively narrower range. For example, the lowest curve corresponding to a chamber pressure of 5 Torr, is kept between about 220° C. and about 270° C., for wafer temperature of 620° C. Another observation is the effect of pressure in the deposition chamber 340 on the temperature measurements. For example, at TC6 temperature drops from above 280° C. when pressure is at 1 Torr to about 230° C. when pressure is increased to 5 Torr.

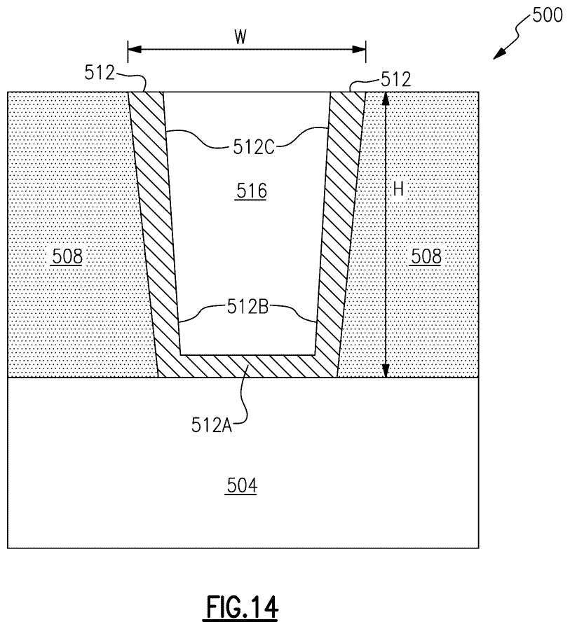

FIG. 13 illustrates, by way of example only, an example precursor delivery sequence for delivering one or more precursors using a temperature-controlled showerhead assembly (e.g., showerhead assembly 300B), according to some embodiments. A first and second precursor inlets at the injector block are connected to first and second precursor delivery lines arranged as described above, e.g., with respect to FIG. 1. Thus two precursor delivery sequences are shown by two charts in FIG. 13, respectively. In each chart the vertical axis is flow rate (Q) and the horizontal axis is time (t). ALD cycles of the two charts comprises a first sub-cycle for exposing the substrate 356 to the first precursor (e.g., TiCl₄), and a second sub-cycle for exposing the substrate 356 to the second precursor (e.g., NH₃). Each of the precursor ALD valves may be a three-port valve, and in some implementations, a continuous purge (CP) gas, e.g., an inert gas, may be flown through the ALD valves while the substrate 356 is exposed to the first precursor and/or the second precursor. In the illustrated example charts, the CP gas used is N₂. When introduced simultaneously into the deposition chamber 340, the CP gas and a precursor are mixed in the diffusing/mixing cavity 312 prior to being introduced into the deposition chamber 340, as described above. In the illustrated embodiment of FIG. 13, each of the first and second sub-cycles further comprises a rapid purge (RP) by an inert gas following the exposure to one or both of the first and second precursors, respectively. In FIG. 13, the rapid purge gas is N₂, which is the same as the continuous purge gas used. The rapid purge may be performed using a purge ALD valve as describe above. The rapid purge has higher flow rate in magnitude than the continuous purge, as shown in FIG. 13.

The deposition system 100 according to above described embodiments are particularly advantageous for forming a thin film on a substrate that comprises high aspect ratio structures having an opening width less than 1 micron, 500 nm, 200 nm, 100 nm, 50 nm, 20 nm or a value in a range defined by any of these values, an aspect ratio exceeding 5, 10, 20, 50, 100, 200 or a value in a range defined by any of these values, and an area density such that the surface area is greater than that of a planar substrate as described above. Substrates having such topography may be conformally coated with thin films comprising TiN, TiSiN and/or TiAlN or another suitable thin film according to embodiments with a step coverage as defined above that exceeds 50%, 60%, 70%, 80%, 90%, 95%, or has a value in a range defined by any of these values or higher.

One measure of conformality in the context of high aspect ratio structures for which high uniformity is referred to herein as step coverage. A high aspect ratio structure may be, e.g., a via, a hole, a trench, a cavity, a protrude or a similar structure. By way of an illustrative example, FIG. 14 schematically illustrates a semiconductor structure 500 having an example high aspect ratio structure 516 formed therein, to illustrate some example metrics of defining and/or measuring conformality of thin films formed on high aspect ratio structures. The illustrated high aspect ratio structure 516 is coated with a thin film 512, e.g., TiN layer deposited according to some embodiments, having different thicknesses at different portions thereof. As described herein, a high aspect ratio structure has an aspect ratio, e.g., a ratio defined as a depth or height (H) divided by a width (W) at the opening region of the high aspect ratio structure 516, that exceeds 1. In the illustrated example, the high aspect ratio structure 516 is a via formed through a dielectric layer 508, e.g., an intermetal dielectric (ILD) layer, disposed on a semiconductor substrate 504, such that a bottom surface of the high aspect ratio structure 516 exposes the underlying semiconductor 504. The thin film 512 can coat different surfaces of the high aspect ratio structure 516 with different thicknesses. As described herein, one metric for defining or measuring the conformality of a thin film formed in a high aspect ratio is referred to as step coverage. A step coverage may be defined as a ratio between a thickness of a thin film at a lower or bottom region of a high aspect ratio structure and a thickness of the thin film at an upper or top region of the high aspect ratio structure. The upper or top region may be a region of the high aspect ratio structure at a relatively small depth at, e.g., 0-10% or 0-25% of the H measured from the top of the opening. The lower or bottom region may be a region of the high aspect ratio structure at a relatively high depth at, e.g., 90-100% or 75-100% of the H measured from the top of the opening. In some high aspect ratio structures, a step coverage may be defined or measured by a ratio of thicknesses of the thin film 512A formed at a bottom surface to the thin film 512C formed at upper or top sidewall surfaces of the high aspect ratio structure. However, it will be appreciated that some high aspect ratio structures may not have a well-defined bottom surface or a bottom surface having small radius of curvature. In these structures, a step coverage may be more consistently defined or measured by a ratio of thicknesses of the thin film 512B formed at a lower or bottom sidewall surface to the thin film 512C formed at an upper or top sidewall surfaces of the high aspect ratio structure.

The deposition system 100 according to the embodiments, at least in part due to the relatively constant temperature uniformity of the showerhead body 308 and effective diffusion and/or mixing of the precursors with the purge gases, gives rise to substantial improvement in step coverage in high aspect ratio structures. By employing the temperature-controlled showerhead assembly 300B according to the embodiments, high aspect ratio structures having an aspect ratio exceeding 1, 2, 5, 10, 20, 50, 100, 200 or a value in a range defined by any of these values may be conformally coated with a thin film such as a TiN film according to embodiments with a step coverage as defined herein that exceeds 70%, 80%, 90%, 95%, or has a value in a range defined by any of these values. Thus obtained step coverage values represent an improvement over corresponding step coverage values obtained using a comparable thin film deposition system showerhead assemblies without proper temperature control 5%, 10%, 15%, 20% or a value in a range defined by any of these values.

### Additional Examples I

1. A temperature-controlled showerhead assembly configured to deliver a plurality of precursors into an atomic layer deposition (ALD) chamber, the showerhead assembly comprising:
a showerhead comprising a solid body portion and a gas diffusing cavity formed therethrough at a central region thereof, wherein the showerhead is configured to diffuse the precursors in the gas diffusing cavity prior being introduced into the ALD chamber;
a network of cooling channels formed over the showerhead and configured to conduct heat away from the showerhead; and
a network of heating elements contacting the solid body portion and configured to supply heat to the showerhead.

2. A temperature-controlled showerhead assembly configured to deliver a plurality of precursors into an atomic layer deposition (ALD) chamber, the showerhead assembly comprising:
a showerhead comprising:
   a solid body portion having a substantially flat outer surface facing away from a susceptor while having an inner surface facing the susceptor that is tapered such that a thickness of the solid body portion increases from a central region towards an edge portion thereof, and
   a cone-shaped gas diffusing cavity formed therethrough at the central region thereof and configured to diffuse the precursors prior to being introduced into the ALD chamber; and
a network of cooling channels and a network of heating elements formed at different vertical levels and configured such that during deposition, the inner surface of the solid body portion is maintained at a temperature that is at least 20° C. higher than a temperature of a liquid coolant filling the cooling channels.

3. A temperature-controlled showerhead assembly configured to deliver a plurality of precursors into an atomic layer deposition (ALD) chamber, the showerhead assembly comprising:
a showerhead comprising a solid body portion and a gas diffusing cavity formed therethrough at a central region thereof, wherein the showerhead is configured to diffuse the precursors in the gas diffusing cavity prior being introduced into the thin film deposition chamber;
a network of cooling channels formed over the showerhead and configured to conduct heat away from the showerhead;
a network of heating elements configured to supply heat to the showerhead; and
a thermally insulating film vertically interposed between the cooling channels and the heating elements and configured to limit heat transfer therebetween.

4. The showerhead assembly of Examples 2 or 3, wherein the heating elements contact the solid portion of the showerhead.

5. The showerhead assembly of Examples 1 or 3, wherein the solid body portion has a substantially flat outer surface facing away from a susceptor while having an inner surface facing the susceptor that is tapered such that a thickness of the solid body portion increases towards an edge portion thereof.

6. The showerhead assembly of Examples 1 or 3, wherein the gas diffusing cavity is a cone-shaped gas diffusing cavity.

7. The showerhead assembly of Examples 1 or 3, wherein the network of cooling channels and the network of heating elements are formed at different vertical levels and configured such that during deposition, the inner surface of the solid body portion is maintained at a temperature that is at least 20° C. higher than a temperature of a liquid coolant filling the cooling channels.

8. The showerhead assembly of Examples 1 or 2, wherein the cooling channels and the heating elements are thermally insulated from each other by a thermally insulating film vertically interposed therebetween.

9. The showerhead assembly of any one of the above Examples, wherein the showerhead further comprises a plurality of thermocouples embedded in the solid body portion and disposed within 0.5 in. from an inner surface thereof facing a susceptor.

10. The showerhead assembly of any one of the above Examples, wherein the outer surface of the showerhead is sloped in a radial direction to have a neck angle, relative to a horizontal direction, which is less than 10 degrees.

11. The showerhead assembly of any one of the above Examples, wherein the gas diffusing cavity is a cone-shaped diffusing cavity having a sidewall thereof to have a cone angle, relative to a vertical direction, that is less than 10 degrees.

12. The showerhead assembly of any one of the above Examples, wherein a distance between a bottom-most surface of the solid body portion facing the susceptor and the susceptor is less than 0.3″.

13. The showerhead assembly of any one of the above Examples, wherein the gas diffusing cavity is a cone-shaped diffusing cavity having a diameter that is less than 30% of a diameter of the showerhead.

14. The showerhead assembly of any one of the above Examples, wherein the showerhead assembly further comprises an injector block disposed over the showerhead, wherein the injector comprises a plurality of injector channels formed therein and configured to direct the precursors in slanted directions into the gas diffusing cavity.

15. The showerhead assembly of Example 14, wherein the slanted directions are such that the precursors exiting from the injector channels are directed towards a sidewall of the gas diffusing cavity.

16. The showerhead assembly of Example 14, further comprising a mixing chamber formed within the gas diffusing cavity, and wherein the plurality of injector channels are configured to direct the precursors into the mixing chamber prior to being introduced into the ALD chamber.

17. The showerhead assembly of Example 16, wherein the mixing chamber comprises a plurality of injectors configured to inject the precursors into the ALD chamber.

18. The showerhead assembly of any one of the Examples, wherein the cooling channels and the heating elements do not overlap in a vertical direction.

19. The showerhead assembly of any one of the above Examples, wherein the cooling channels and the heating elements that are vertically interposed by a thermally insulating film comprising a polymer film.

20. The showerhead assembly of Example 19, wherein the polymer film comprises polyetheretherketone (PEEK).

21. The showerhead assembly of Example 19, wherein the polymer film has a thickness between 0.020 and 0.040 inches.

22. The showerhead assembly of any one of the above Examples, wherein the cooling channels are filled with a liquid coolant that is maintained at a substantially constant temperature by a heat exchanger.

23. The showerhead assembly of any one of the above Examples, wherein the heating elements comprise resistive heating elements.

24. The showerhead assembly of any one of the above Examples, wherein the network of cooling channels and the network of heating elements are configured such that during deposition, the inner surface of the solid body portion facing the susceptor is maintained at a temperature of 150-240° C.

25. The showerhead assembly of Example 24, wherein the cooling channels are filled with a liquid coolant that is maintained at a substantially constant temperature of 120-220° C.

26. The showerhead assembly of Example 24, wherein the heating elements are configured to dissipate 500 W-2000 W.

27. The showerhead assembly of Example 24, wherein the ALD chamber comprises a susceptor is configured to heat a substrate between 300° C. and 700° C.

28. The showerhead assembly of any one of the above Examples, wherein the heating elements do not contact the solid body portion.

29. The showerhead assembly of any one of the above Examples, wherein the heating elements do not contact the cooling channels.

### Additional Examples II

1. A temperature-controlled showerhead assembly configured to deliver a plurality of gases into a cyclic deposition chamber, the showerhead assembly comprising:
a showerhead body comprising a cavity formed therethrough and at a central region thereof, wherein the cavity is configured to diffuse or mix the gases prior to introducing the gases into the deposition chamber;
a network of cooling channels configured to conduct heat away from the showerhead body; and
a network of heating elements configured to supply heat to the showerhead body, wherein the network of heating elements is disposed closer to an upper surface of the showerhead body relative to the cooling channels.

2. The showerhead assembly of Example 1, wherein the cooling channels and the network of heating elements are disposed at different vertical levels.

3. The showerhead assembly of Example 2, wherein the cooling channels and the network of heating elements are thermally insulated from each other by an insulation layer interposed therebetween.

4. The showerhead assembly of Example 3, wherein the cooling channels and the network of heating elements laterally surround the cavity.

5. The showerhead assembly of Example 4, wherein the cavity has a truncated cone shape that is elongated in a vertical direction and has a width that increases in a direction towards a susceptor disposed below the showerhead assembly.

6. The showerhead assembly of Example 1, wherein the showerhead assembly further comprises an injector block disposed over the showerhead body, wherein the injector block comprises a plurality of channels formed therein for flowing different gases to direct the different gases in different directions into the cavity.

7. The showerhead assembly of Example 6, wherein the cavity is configured to mix two different gases prior to being introduced into the deposition chamber.

8. The showerhead assembly of Example 7, wherein one of the two different gases is an inert gas and the other of the two different gases is a reactant.

9. A temperature-controlled showerhead assembly configured to deliver a plurality of gases into a cyclic deposition chamber, the showerhead assembly comprising:
a showerhead body having a substantially flat outer surface facing away from a susceptor while having an inner surface facing the susceptor that is tapered such that a thickness of the showerhead body increases from a central region towards an edge portion thereof;
a cavity formed through the showerhead body at the central region and configured to diffuse or mix the gases prior to introducing the gases into the deposition chamber; and
a network of cooling channels and a network of heating elements formed at different vertical levels.

10. The showerhead assembly of Example 9, wherein the network of cooling channels and the network of heating elements are configured such that during deposition, the inner surface of the showerhead body is maintained at a temperature that is at least 20° C. higher relative to a temperature of a liquid coolant filling the cooling channels.

11. The showerhead assembly of Example 9, wherein the cooling channels and the network of heating elements are thermally insulated from each other by a thermally insulating film vertically interposed therebetween.

12. The showerhead assembly of Example 9, wherein the showerhead assembly further comprises a plurality of thermocouples disposed within 0.5 in. from the inner surface of the showerhead body facing a susceptor.

13. The showerhead assembly of Example 9, wherein the outer surface of the showerhead body is sloped in a radial direction to have a neck angle, relative to a horizontal direction, of less than 10 degrees.

14. The showerhead assembly of Example 9, wherein the cavity is a cone-shaped cavity having a sidewall thereof to have a cone angle, relative to a vertical direction, that is less than 10 degrees.

15. The showerhead assembly of Example 9, wherein a distance between a bottom-most surface of the showerhead body facing a susceptor and an upper surface of the susceptor is less than 0.3″.

16. A temperature-controlled showerhead assembly configured to deliver a plurality of gases into a cyclic deposition chamber, the showerhead assembly comprising:
a showerhead body comprising a cavity formed therethrough and at a central region thereof, wherein the cavity is configured to diffuse or mix the gases prior to introducing the gases into the deposition chamber;
a network of cooling channels formed over the showerhead body and configured to conduct heat away from the showerhead;
a network of heating elements configured to supply heat to the showerhead; and
a thermally insulating film vertically interposed between the cooling channels and the network of heating elements.

17. The showerhead assembly of Example 16, wherein a lateral footprint occupied by the network of cooling channels is enclosed within a lateral footprint occupied by the network of heating elements.

18. The showerhead assembly of Example 16, wherein the thermally insulation film comprises a polymer film.

19. The showerhead assembly of Example 18, wherein the polymer film comprises polyetheretherketone (PEEK).

20. The showerhead assembly of Example 19, wherein the polymer film has a thickness between 0.020 and 0.040 inches.

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

What is claimed is:

1. A temperature-controlled showerhead assembly configured to deliver a plurality of gases into a cyclic deposition chamber, the showerhead assembly comprising:
a showerhead body comprising a cavity formed therethrough and at a central region thereof, wherein the cavity is configured to diffuse or mix the gases prior to introducing the gases into the deposition chamber;
a network of cooling channels configured to conduct heat away from the showerhead body; and
a network of heating elements configured to supply heat to the showerhead body, wherein the network of heating elements is disposed closer to an upper surface of the showerhead body relative to the cooling channels.

2. The showerhead assembly of claim 1, wherein the cooling channels and the network of heating elements are disposed at different vertical levels.

3. The showerhead assembly of claim 2, wherein the cooling channels and the network of heating elements are thermally insulated from each other by an insulation layer interposed therebetween.

4. The showerhead assembly of claim 3, wherein the cooling channels and the network of heating elements laterally surround the cavity.

5. The showerhead assembly of claim 4, wherein the cavity has a truncated cone shape that is elongated in a vertical direction and has a width that increases in a direction towards a susceptor disposed below the showerhead assembly.

6. The showerhead assembly of claim 1, wherein the showerhead assembly further comprises an injector block disposed over the showerhead body, wherein the injector block comprises a plurality of channels formed therein for flowing different gases to direct the different gases in different directions into the cavity.

7. The showerhead assembly of claim 6, wherein the cavity is configured to mix two different gases prior to being introduced into the deposition chamber.

8. The showerhead assembly of claim 7, wherein one of the two different gases is an inert gas and the other of the two different gases is a reactant.

9. A temperature-controlled showerhead assembly configured to deliver a plurality of gases into a cyclic deposition chamber, the showerhead assembly comprising:
a showerhead body having a substantially flat outer surface facing away from a susceptor while having an inner surface facing the susceptor that is tapered such that a thickness of the showerhead body increases from a central region towards an edge portion thereof;
a cavity formed through the showerhead body at the central region and configured to diffuse or mix the gases prior to introducing the gases into the deposition chamber; and
a network of cooling channels and a network of heating elements formed at different vertical levels.

10. The showerhead assembly of claim 9, wherein the network of cooling channels and the network of heating elements are configured such that during deposition, the inner surface of the showerhead body is maintained at a temperature that is at least 20° C. higher relative to a temperature of a liquid coolant filling the cooling channels.

11. The showerhead assembly of claim 9, wherein the cooling channels and the network of heating elements are thermally insulated from each other by a thermally insulating film vertically interposed therebetween.

12. The showerhead assembly of claim 9, wherein the showerhead assembly further comprises a plurality of thermocouples disposed within 0.5 in. from the inner surface of the showerhead body facing a susceptor.

13. The showerhead assembly of claim 9, wherein the outer surface of the showerhead body is sloped in a radial direction to have a neck angle, relative to a horizontal direction, of less than 10 degrees.

14. The showerhead assembly of claim 9, wherein the cavity is a cone-shaped cavity having a sidewall thereof to have a cone angle, relative to a vertical direction, that is less than 10 degrees.

15. The showerhead assembly of claim 9, wherein a distance between a bottom-most surface of the showerhead body facing a susceptor and an upper surface of the susceptor is less than 0.3″.

16. A temperature-controlled showerhead assembly configured to deliver a plurality of gases into a cyclic deposition chamber, the showerhead assembly comprising:
a showerhead body comprising a cavity formed therethrough and at a central region thereof, wherein the cavity is configured to diffuse or mix the gases prior to introducing the gases into the deposition chamber;
a network of cooling channels formed over the showerhead body and configured to conduct heat away from the showerhead;
a network of heating elements configured to supply heat to the showerhead; and
a thermally insulating film vertically interposed between the cooling channels and the network of heating elements.

17. The showerhead assembly of claim 16, wherein a lateral footprint occupied by the network of cooling channels is enclosed within a lateral footprint occupied by the network of heating elements.

18. The showerhead assembly of claim 16, wherein the thermally insulation film comprises a polymer film.

19. The showerhead assembly of claim 18, wherein the polymer film comprises polyetheretherketone (PEEK).

20. The showerhead assembly of claim 19, wherein the polymer film has a thickness between 0.020 and 0.040 inches.
